(19) United States
(12) Patent Application Publication
(10) Pub. No.: US 2026/0203482 A1
(43) Pub. Date: Jul. 16, 2026

(54) IDENTIFICATION AND MAPPING OF FLOW BAFFLES

(71) Applicant: Saudi Arabian Oil Company, Dhahran (SA)

(72) Inventors: Raheel R. Baig, Dhahran (SA); Jibran Ayub, Dhahran (SA)

(21) Appl. No.: 19/018,540

(22) Filed: Jan. 13, 2025

(51) Int. Cl. G06F 30/28

(52) U.S. Cl. CPC G06F 30/28

(57) ABSTRACT

Disclosed are methods, systems, and computer-readable media to perform operations including receiving, measurements for a plurality of wells from a Formation Testing and Sampling (FTS) tool; mapping the plurality of data points to a simulation model that represents a reservoir; obtaining, from the simulation model, an initial water saturation value at each data point; determining an initial oil pressure and an initial water pressure at each data point; obtaining, from one or more well logs, a second water saturation value at each data point; determining a reservoir saturation status at each data point; clustering the plurality of data points into one or more clusters; identifying at least one pressure baffle on a boundary between every two adjacent clusters; generating a two-dimensional (2D) map for each geological layer; providing the 2D map for each geological layer to the simulation model; and performing a calibration of the simulation model.

### TECHNICAL FIELD

This disclosure relates generally to hydrocarbon exploration, drilling, and production, and more particularly to baffle identification.

### BACKGROUND

Existing baffle analysis is performed by manually identifying baffling intervals on a plot of pressure versus depth. As the process is manual, it is subjective to engineering knowledge and experience and has the potential to overlook vital information. It is tedious to manually analyze data at multiple well locations and at different times of measurement for a large number of wells.

### SUMMARY

The present disclosure describes automatic identification of pressure baffles and simulation model calibration using the identified pressure baffles.

According to one innovative aspect of the present disclosure, a method for baffle identification implemented by one or more processors is disclosed. In one aspect, the method can include: receiving, measurements for a plurality of wells from a Formation Testing and Sampling (FTS) tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a two-dimensional (2D) map for each geological layer of the reservoir indicating a location of each pressure baffle; providing the 2D map for each geological layer to the simulation model as a history match calibration parameter; and performing a calibration of the simulation model using the history match calibration parameter.

Other aspects include devices, apparatuses, systems, and computer programs for performing the aforementioned method.

The innovative method can include other optional features. For example, in some implementations, wherein clustering the plurality of data points into the one or more clusters further comprises: for each data point: identifying a true vertical depth (TVD) and an actual pressure value at a current data point; predicting a pressure value at the next adjacent data point based on the actual pressure value at the current data point, the fluid density, and a difference between a TVD of the next adjacent data point and the TVD of the current data point; comparing an actual pressure value at the next adjacent data point with the predicted pressure value; and assigning the next adjacent data point into a cluster based on the comparison.

In some implementations, wherein assigning the next adjacent data point into the cluster comprises: in response to the actual pressure value at the next adjacent data point being within a first pressure range, assigning the next adjacent data point into a cluster the same as that of the current data point; in response to the actual pressure value at the next adjacent data point being within a second pressure range, assigning the next adjacent data point into a new cluster different from that of the current data point.

In some implementations, wherein the fluid density comprises a maximum density value and a minimum density value, and the predicted pressure value comprises a maximum predicted pressure value and a minimum predicted pressure value corresponding to the maximum density value and the minimum density value, respectively.

In some implementations, wherein each grid cell includes a row (I) index, a column (J) index and a layer (K) index.

In some implementations, wherein the reservoir saturation status at each data point indicates whether each data point is located in an oil zone, a swept zone, an aquifer zone, or a low-quality reservoir zone.

In some implementations, the method further comprising: determining a location of at least one pressure baffle; determining that the at least one pressure baffle is an intra-geological layer pressure baffle or an inter-geological layer pressure baffle based on the location of the at least one pressure baffle.

In some implementations, wherein identifying the at least one pressure baffle on the boundary between every two adjacent clusters further comprises identifying the at least one pressure baffle between a last data point in a first cluster and a first data point in a second cluster adjacent to the first cluster.

In some implementations, wherein generating the 2D map for each geological layer of the reservoir comprises mapping pressure baffles identified in the plurality of wells aerially in a XY direction using a 2D surface mapping algorithm.

In some implementations, wherein the 2D surface mapping algorithm comprises a kriging interpolation.

In some implementations, wherein performing the calibration of the simulation model comprises adjusting a simulation model pressure response and a simulation model water-cut response using the history match calibration parameter.

According to another innovative aspect of the present disclosure, a non-transitory, computer-readable medium storing one or more instructions executable by a computer system to perform one or more operations, comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

In some implementations, wherein clustering the plurality of data points into the one or more clusters further comprises: for each data point: identifying a true vertical depth (TVD) and an actual pressure value at a current data point; predicting a pressure value at the next adjacent data point based on the actual pressure value at the current data point, the fluid density, and a difference between a TVD of the next adjacent data point and the TVD of the current data point; comparing an actual pressure value at the next adjacent data point with the predicted pressure value; and assigning the next adjacent data point into a cluster based on the comparison.

In some implementations, wherein assigning the next adjacent data point into the cluster comprises: in response to the actual pressure value at the next adjacent data point being within a first pressure range, assigning the next adjacent data point into a cluster the same as that of the current data point; in response to the actual pressure value at the next adjacent data point being within a second pressure range, assigning the next adjacent data point into a new cluster different from that of the current data point.

In some implementations, wherein the fluid density comprises a maximum density value and a minimum density value, and the predicted pressure value comprises a maximum predicted pressure value and a minimum predicted pressure value corresponding to the maximum density value and the minimum density value, respectively.

In some implementations, wherein each grid cell includes a row (I) index, a column (J) index and a layer (K) index.

In some implementations, wherein the reservoir saturation status at each data point indicates whether each data point is located in an oil zone, a swept zone, an aquifer zone, or a low-quality reservoir zone.

In some implementations, the operations further comprising: determining a location of at least one pressure baffle; determining that the at least one pressure baffle is an intra-geological layer pressure baffle or an inter-geological layer pressure baffle based on the location of the at least one pressure baffle.

In some implementations, wherein identifying the at least one pressure baffle on the boundary between every two adjacent clusters further comprises identifying the at least one pressure baffle between a last data point in a first cluster and a first data point in a second cluster adjacent to the first cluster.

According to another innovative aspect of the present disclosure, a computer-implemented system, comprising: one or more computers; and one or more computer memory devices interoperably coupled with the one or more computers and having tangible, non-transitory, machine-readable media storing one or more instructions that, when executed by the one or more computers, perform one or more operations, comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

The described subject matter can be implemented using a computer-implemented method; a non-transitory, computer-readable medium storing computer-readable instructions to perform the computer-implemented method; and a computer-implemented system comprising one or more computer memory devices interoperably coupled with one or more computers and having tangible, non-transitory, machine-readable media storing instructions that, when executed by the one or more computers, perform the computer-implemented method/the computer-readable instructions stored on the non-transitory, computer-readable medium.

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### BRIEF DESCRIPTION OF THE FIGURES

FIGS. 1A and 1B illustrate example post-production FTS pressure data plots, according to some implementations.

FIG. 2 illustrates baffling effect observed in FTS pressure data, according to some implementations.

FIG. 3 illustrates three categories of reservoir zones as defined by FL_IDs, according to some implementations.

FIG. 4 illustrates an example table of baffles in a well identified based on CL_IDs and BF_IDs, according to some implementations.

FIG. 5 illustrates an example table of inter-layer baffles in multiple wells, according to some implementations.

FIG. 6 illustrates an example 2D baffle map for layer 2, according to some implementations.

FIG. 7 illustrates another example 2D baffle map generated by a baffle identification process, according to some implementations.

FIG. 8 illustrates improvement in simulation model history match quality of an example well, according to some implementations.

FIG. 9 illustrates an improvement in reservoir water-cut history match quality after incorporating baffle regions property that are used for history match calibration, according to some implementations.

FIG. 10 illustrates a flow chart of an example process for automatic baffle identification, according to one or more implementations.

FIG. 11 illustrates a flow chart of an example process for automatic baffle identification, according to some implementations.

FIG. 12 illustrates hydrocarbon production operations that include both one or more field operations and one or more computational operations, which exchange information and control exploration for the production of hydrocarbons, according to some implementations.

FIG. 13 is a schematic illustration of an example controller (or control system) that enables an example system to identify wells where baffles are present and generate a 2D map indicating locations of baffles at each geological layer of a reservoir, according to some implementations.

### DETAILED DESCRIPTION

Conventional techniques identify pressure baffles visually by engineers, which is prone to missing baffle information. Furthermore, it is tedious to manually map the true vertical depths (TVD) in the Formation Testing and Sampling (FTS) data with the K index of a grid cell which is essential for mapping baffles in each geological layer.

This disclosure describes methods and systems for automatically analyzing wellbore FTS pressure data of a large number of wells to identify wells where baffles (or barriers) are present and generating a two-dimensional (2D) map indicating locations of baffles (locations of wells where baffles are present) at each geological layer of a reservoir. 2D maps can be integrated into a simulation model of the reservoir as three-dimensional (3D) baffle regions, leading to improved history matching between the measured FTS pressure/water-cut data and the simulation model pressure/water-cut response.

The disclosed techniques standardize and automate identification of pressure baffles using a clustering technique that reliably identifies breaks in vertical pressure depletion across an oil field reservoir. The baffle information is automatically mapped to a geological or simulation grid for improved reservoir heterogeneity understanding and history matching of a reservoir simulation model. The disclosed techniques can solve both the challenge of human subjectivity and a tedious nature of manually mapping FTS derived reservoir pressure baffle information to a geological or simulation grid.

In oil field operations, reservoir surveillance data, such as FTS pressure data point (hereinafter “FTS point”), is acquired to monitor reservoir behavior and to improve understanding of reservoir characterization. The FTS tool, also known as residual formation testing (RFT) tool or Modular Dynamics Tester (MDT), is an oil field tool that effectively isolates sections of a wellbore formation to perform a mini-flow test and measure downhole parameters including formation pressure. The FTS tests are repeated over regular intervals along a wellbore to acquire a complete formation pressure profile.

The disclosed techniques can map each FTS point to a Row, Column, Layer (IJK) grid cell in a simulation grid representing the reservoir. Each geological layer is identified using a K index of each FTS point. An initial water saturation (Sw) value of each FTS point can be obtained directly from the simulation model. The simulation grid represents volumetric data and used for distribution of a pressure property within a 3D space. Each cell in the simulation grid is identified uniquely by its (I, J, K) coordinates indicating a row index, a column index, and a depth index.

The disclosed techniques can then calculate an initial oil gradient and an initial water gradient for the reservoir based on the input parameters including datum depth, an initial pressure, an initial oil density, and an initial water density. The disclosed techniques can also obtain Sw values for each FTS point directly from Sw logs by mapping TVD defining FTS points to measured depths (MD) of each well, because Sw logs are recorded along the MD).

The disclosed techniques can identify whether each FTS point is in an oil zone, a tight/high Sw zone, or a swept zone using a fluid ID that is generated using rules based on the initial Sw value obtained from the simulation model and Sw values from the Sw logs.

The disclosed techniques can then initiate a baffle identification process including a clustering subprocess and a classification subprocess. For each FTS point starting from the lowest TVD sequentially, a pressure trend prediction is performed for the next FTS point using reservoir fluid densities. A clustering subprocess groups FTS points on the same pressure trend. Any FTS point which deviates from the expected pressure trend beyond a predetermined threshold is identified to be in a different cluster than the previous FTS point. The output of the data clustering subprocess includes clusters for all the FTS points of each well. The disclosed techniques can identify a vertical baffle at a boundary between adjacent clusters and differential depletion between FTS data points.

The disclosed techniques can identify vertical baffles in inter-geological layers and an intra-geological layer based on K index of the simulation grid. Geological layers are defined as a function of range of K index values in the simulation grid, essentially a geological layering key with respect to simulation grid K index. For example, the K indices of subsequent FTS points being in different K index ranges indicates an inter-geological baffle, while the K indices of subsequent FTS points being in the same K index range indicates an intra-geological baffle. The output of the disclosed techniques includes multiple vertical baffles for each well that are mapped as a 2D baffle map for each geological layer.

The 2D baffle maps can help understand the reservoir characterization. The 2D baffle maps can be utilized in the static modeling process for enhanced prediction of geological properties (e.g., rock types, porosity, permeability, and fluid distribution) between wells. As a part of the dynamic history matching phase of reservoir modeling, the 2D baffle maps are exported to 3D simulation model and used as vertical connectivity calibration regions for improved history matching between simulation model pressure response and FTS pressure data and history matching between simulation model water-cut response and measured water-cut data.

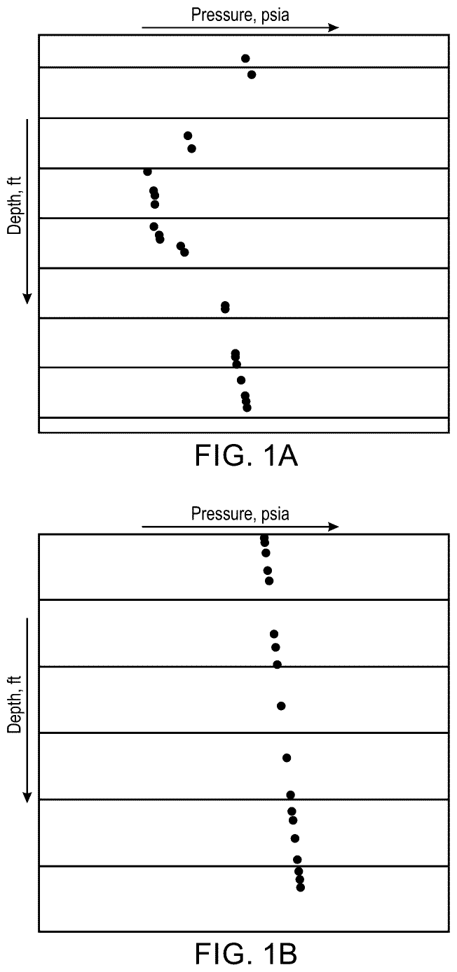

FIGS. 1A and 1B illustrate example post-production FTS pressure data plots, according to some implementations. FIG. 1A indicates the presence of pressure baffles due to differential depletion between FTS points. In FIG. 1B, no pressure baffles are observable as all FTS points lie on the same pressure trend.

In a homogenous reservoir, all FTS points are observed to be uniformly depleted at the same pressure gradient, as shown in FIG. 1B. However, in a heterogenous reservoir, different sections of the rock formations may deplete differently with respect to each other (known as differential depletion) which may indicate presence of baffles in the reservoir, as shown in FIG. 1A.

### Concept Description

At an initial point before any significant hydrocarbon production, an oil field reservoir is in an equilibrium state. An initial pressure in the reservoir is a function of an initial fluid pressure gradient and a vertical depth, according to Equation (1).

$${P}_{i , fluid} = {( \frac{d P}{d D} )}_{i , fluid} * D , \qquad ( 1 )$$

where P_{i,fluid} is an initial pressure of a fluid (e.g., oil or water),

$${( \frac{d P}{d D} )}_{i , fluid}$$

is a fluid pressure gradient (unit: psi/ft) calculated by multiplying the specific gravity of the fluid with the gradient of pure fresh water having a density of 1 gram/CC, and D is a depth in feet.

With production from the reservoir over time, different sections of the reservoir may deplete at different magnitudes (differential depletion), indicating the presence of vertical heterogeneity, such as variation in rock properties (e.g., permeability) or the presence of extensive low rock quality (e.g., shale) dominated intervals. In a layered heterogeneous reservoir, differential depletion is usually observed at geological layer boundaries, indicating a difference in connectivity between the adjacent geological layers. The differential depletion indicates presence of pressure baffles.

The pressure baffles can be identified by sequentially checking whether subsequent measured FTS points are following a common pressure gradient. The FTS points on the same gradient deplete with a similar magnitude of pressure gradient with respect to the initial pressure (as shown in FIG. 1B), indicating good pressure communication and no baffles are present. By contrast, if a subsequent FTS point does not align with the expected pressure gradient of the previous FTS point (as shown in FIG. 1A), a pressure baffle is identified.

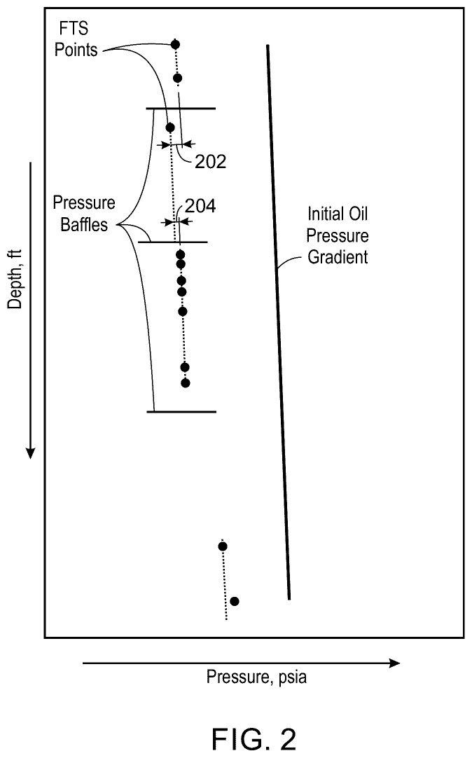

FIG. 2 illustrates baffling effect observed in FTS pressure data, according to some implementations. As shown in FIG. 2, there are three inter-layer pressure baffles identified at the geological layer boundaries. A baffle is identified when the sequence of data points shifts away from a common pressure gradient trend (e.g., an initial oil pressure gradient). The dashed lines in FIG. 2 are aligned with the initial pressure gradient. The “shifts” 202, 204 between the dashed lines indicate the presence of pressure baffles.

FTS data is acquired at different wells over the production life of a reservoir, which enables pressure baffle information to be correlated and mapped between the wells across the reservoir. The pressure baffle information derives from dynamic data (FTS data) that enables engineers to establish accurate understanding of reservoir depletion mechanism.

Automatic Baffle Identification and Mapping with Implementation to Oil Field Data

The input of the baffle identification process includes post-production FTS data for multiple wells, a reservoir simulation model initialized with relevant static and dynamic reservoir inputs, a geological layering key with respect to simulation grid K index, reservoir fluid densities (gas/oil/water) in g/cc units, an initial reservoir pressure at datum depth, a free water level depth, water saturation well logs, the water saturation cut-off value, and the threshold pressure value for pressure baffle identification. In some examples, the FTS data is obtained from an undersaturated two-phase (oil/water) reservoir.

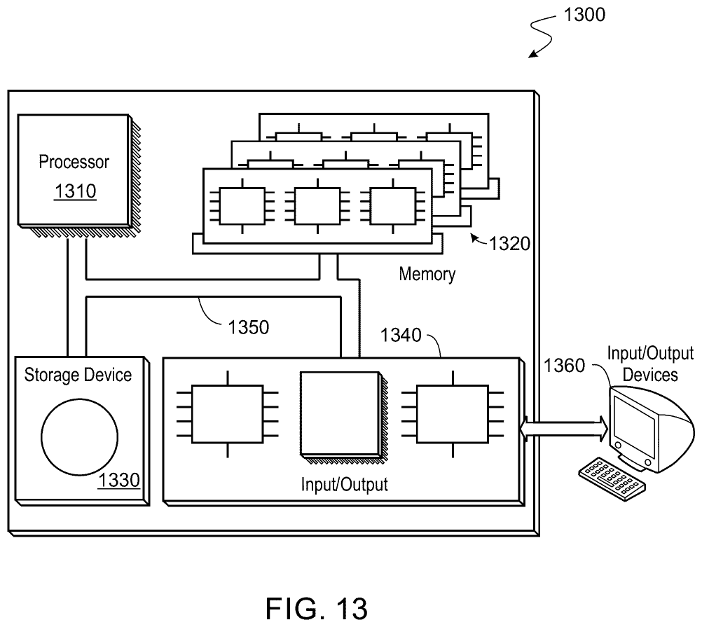

First, the controller (e.g., controller 1300 of FIG. 13) obtains FTS points with respect to TVD for multiple wells, and FTS data of each well is acquired at a specific time. IJK index perforation data for each well is obtained directly from a reservoir simulation model. IJK index perforation data for each well refers to the spatial data that pinpoints where a well is perforated or drilled in a 3D simulation grid. In the context of reservoir simulation, the grid is divided into cells with I (x-direction), J (y-direction), and K (z-direction or vertical direction) indices representing the location of each cell. The controller then automatically obtains the simulation grid cell center depth (CDEPTH) and an initial water saturation (SWINIT) for each IJK perforation index. For each well, the controller maps each FTS point with the corresponding simulation grid IJK cell by correlating the closest CDEPTH to the TVD value. Using the K index of each FTS point, the controller identifies the corresponding geological layer utilizing the geological layering key. The geological layering key defines how the geological formations are mapped onto the simulation grid, e.g., the vertical K index. The geological layering key allows each geological layer to be represented by a specific range of K-index values.

The controller then calculates an initial oil pressure and an initial water pressure for each FTS point using fluid densities and an initial datum pressure. The initial oil/water pressure refers to a virgin pressure in the subsurface reservoir before any impact of fluid production.

The initial oil pressure is calculated according to Equation (2):

$${P}_{oil} = \{ \begin{matrix}{P}_{oil @ datum} - ( \vert {D}_{datum} - TVD \vert * {( \frac{dP}{dD} )}_{i , oil} ) & if ( TVD < {D}_{datum} ) \\ {P}_{oil @ datum} + ( \vert {D}_{datum} - TVD \vert * {( \frac{dP}{dD} )}_{i , oil} ) & if ( TVD > {D}_{datum} )\end{matrix} . \qquad ( 2 )$$

The pressure of water and the pressure of oil are equal at the free water level (FWL). The initial pressure of water is calculated according to Equations (3) and (4):

$${P}_{water @ FWL} = {P}_{oil @ datum} + ( \vert {D}_{datum} - {D}_{FWL} \vert * {( \frac{dP}{dD} )}_{i , oil} ) , and \qquad ( 3 )$$

$${P}_{water} = \{ \begin{matrix}{P}_{water @ FWL} - ( \vert {D}_{FWL} - TVD \vert * {( \frac{dP}{dD} )}_{i , water} ) & if ( TVD < {D}_{FWL} ) \\ {P}_{water @ FWL} + ( \vert {D}_{FWL} - TVD \vert * {( \frac{dP}{dD} )}_{i , water} ) & if ( TVD > {D}_{FWL} )\end{matrix} . \qquad ( 4 )$$

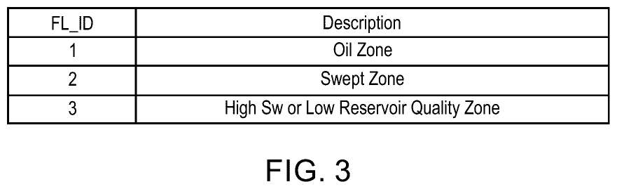

Second, the controller obtains the water saturation logs of each well and obtains the water saturation value (LOGSW) for each FTS point in a well by converting a TVD value in the FTS data to an MD value along a well trajectory. The controller uses a new reservoir fluid identification parameter (FL_ID) to classify each FTS point into three categories according to FIG. 3.

FIG. 3 illustrates three categories of reservoir zones as defined by the FL_ID parameter, according to some implementations. FL_ID is calculated based on the criteria defined in equation (5) below. FL_ID identifies whether the section of a reservoir as measured by an FTS point is in an oil zone (FL_ID=1), a swept zone (FL_ID=2), or a high Sw or tight (low quality) reservoir zone (FL_ID=3). The swept zone is a part of the reservoir where the original oil has been displaced or mobilized by the injected fluid or aquifer fluid, leading to a reduction in oil saturation and typically an increase in the saturation of the injected fluid or aquifer fluid. The last category (FL_ID=3) can either be an aquifer if the zone is below the free water level or a low-quality reservoir zone if the zone is above the free water level.

$$FL\_ID = \{ \begin{matrix}1 & if ( LOGSW \leq {S}_{{w}_{Cutoff}} and SWINIT \leq {S}_{{w}_{Cutoff}} ) \\ 2 & if ( LOGSW \geq {S}_{{w}_{Cutoff}} and SWINIT < {S}_{{w}_{Cutoff}} ) \\ 3 & if ( LOGSW \geq {S}_{{w}_{Cutoff}} and SWINIT \geq {S}_{{w}_{Cutoff}} )\end{matrix} , \qquad ( 5 )$$

where S_{w}_{_{Cutoff}} is the water saturation cut-off fraction.

Third, the controller initiates a physics driven baffle identification process. The process sequentially checks each FTS data point for each well starting from the FTS data point having the lowest TVD. The controller predicts the FTS pressure at the next data point using the equation (6) below. The prediction uses the physical principle of pressure-depth relationship as a function of the reservoir fluid densities. The process can cluster all FTS points of each well into distinct clusters whereby points in each cluster follow a common pressure gradient trend.

$${P}_{pred , n + 1} = {P}_{n} + ( {TVD}_{n + 1} - {TVD}_{n} ) * {( \frac{dP}{dD} )}_{fluid} , \qquad ( 6 )$$

where P_{pred,n+1} is the predicted pressure at the next data point, Pₙ is the actual FTS pressure value at the current data point, TVDₙ₊₁ is the TVD value of the next data point and TVDₙ is the TVD value of the current data point,

$${( \frac{dP}{dD} )}_{fluid}$$

is the fluid gradient (unit psi/ft), which can be calculated using equation (7), where p is fluid density in lb/ft³.

$${( \frac{dP}{dD} )}_{fluid} = ρ * 0.4 33. \qquad ( 7 )$$

The process starts with assigning the first FTS point a cluster identification number, CL_ID, equal to 1. The controller calculates minimum and maximum predicted pressures using the minimum and maximum fluid densities for the next FTS point. The calculation is performed for both oil and water phases using the respective fluid densities (oil density or water density). According to equation (8), if the actual FTS pressure value at the next FTS point is within a range [(P_{pred,min,n+1}−A), (P_{pred,max,n+1}+A)], the next FTS point is assigned the same cluster identification number as the current FTS point. If the actual FTS pressure value at the next FTS point is not within a range ((P_{pred,min,n+1}−A), (P_{pred,max,n+1}+A)), the next FTS point is assigned a different cluster identification number. The process is repeated sequentially for all FTS points for each well. The fluid density used in the calculation depends on a category (FL_ID) of a reservoir zone where each FTS point is located. For example, if the next FTS point is located in a reservoir zone with a category of FL_ID=1, an oil density is used to calculate the minimum and maximum predicted pressures. If the next FTS point is located in a reservoir zone with a category of FL_ID=2 or 3, a water density is used for calculating the minimum and maximum predicted pressures. Each FTS point is assigned with CL_ID, and thus an array of cluster identification numbers CL_IDs is generated for each well.

$${CL\_ID}_{n + 1} = \{ \begin{matrix}{CL\_ID}_{n} & if ( ( {P}_{n + 1} \geq ( {P}_{pred , m i n , n + 1} - A ) ) and ( {P}_{n + 1} \leq ( {P}_{pred , m ax , n + 1} + A ) ) ) \\ {CL\_ID}_{n} + 1 & if ( ( {P}_{n + 1} < ( {P}_{pred , m i n , n + 1} - A ) ) and ( {P}_{n + 1} > ( {P}_{pred , m ax , n + 1} + A ) ) )\end{matrix} , \qquad ( 8 )$$

where Pₙ₊₁ is the actual FTS pressure value at the next FTS point, P_{pred,max,n+1} is the maximum predicted pressure at the next data point using the maximum fluid pressure gradient in equation (6), P_{pred,min,n+1} is the minimum predicted pressure at the next data point using the minimum fluid pressure gradient in equation (6), and A is the predetermined threshold pressure value.

After determining the CL_ID for each FTS point, the controller can identify baffles at the boundary of each cluster by defining a Boolean parameter BF_ID. A baffle is identified between the last data point in a cluster and the first data point in an adjacent cluster. For example, the first baffle is identified between the last data point in cluster 1 and the first data point in cluster 2. The controller also can also identify whether each baffle is an inter-layer baffle or an intra-layer baffle. For example, the controller can determine a first geological layer for the last data point in cluster 1 and a second geological layer for the first data point in cluster 2. If the first geological layer and the second geological layer are the same, the first baffle is classified as an intra-layer baffle. If the first geological layer and the second geological layer are different, the first baffle is classified as an inter-layer baffle. This process is repeated for each well and each well corresponds to an array of BF_IDs.

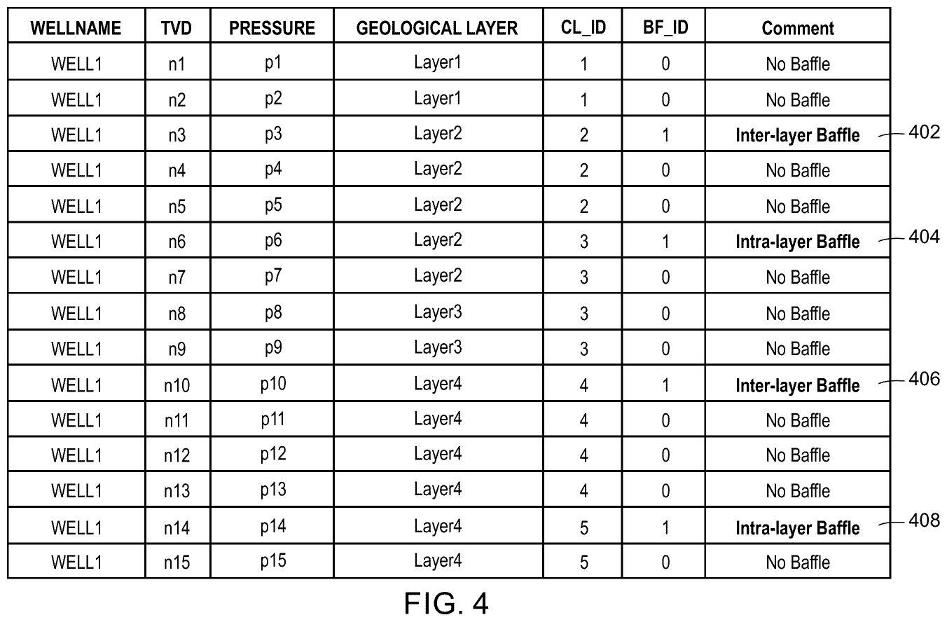

FIG. 4 illustrates an example table of baffles in a well identified based on CL_IDs and BF_IDs, according to some implementations. FIG. 4 indicates baffle information for each FTS point for WELL 1. Inter-layer baffle 402 is identified on the boundary of layer 1 and layer 2. Intra-layer baffle 404 is identified in layer 2. Inter-layer baffle 406 is identified on the boundary of layer 3 and layer 4. Intra-layer baffle 408 is identified in layer 4. The inter-layer 402 is located on top of layer 2, and the inter-layer 406 is located on top of layer 4.

Four, the controller maps the inter-layer baffles into the simulation model. The simulation model includes multiple geological layers. At each well location, the array of BF_IDs can be used to identify whether a baffle is present on each inter-layer boundary. For each inter-layer boundary, BF_IDs for all wells are mapped aerially in the XY direction using a two-dimensional (2D) surface mapping algorithm such as kriging interpolation. A 2D baffle map is generated for each inter-layer boundary, showing locations of pressure baffles (locations of wells) in the reservoir. Each 2D baffle map is placed between every two geological layers, indicating whether a pressure baffle is present between these two geological layers.

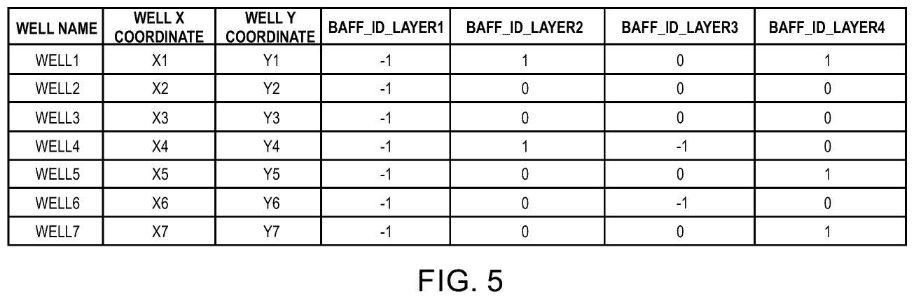

FIG. 5 illustrates an example table of inter-layer baffles in multiple wells, according to some implementations. BAFF_ID=1 indicates that a baffle is present on top of a particular geological layer, BF_ID=0 indicates that a baffle is not present on top of a particular geological layer, and BF_ID=−1 indicates that no baffle data is available on a particular geological layer. For example, BAFF_ID_LAYER1=−1 indicates that no inter-layer baffle is available on layer 1. BAFF_ID_LAYER2=1 for WELL 1 indicates that an inter-layer baffle is present on top of layer 2 in WELL1. BAFF_ID_LAYER3=0 for WELL3 indicates that no inter-layer baffle is present on top of layer 3 in WELL3. BAFF_ID_LAYER4=1 for WELL7 indicates that an inter-layer baffle is present on top of layer 4 in WELL7. The example table of FIG. 5 includes XY coordinates of each well location, and thus a 2D map can be generated for each geological layer (layer 2, layer 3, or layer 4) and mapped aerially using a mapping algorithm such as kriging interpolation. Each geological layer corresponds to its respective 2D map.

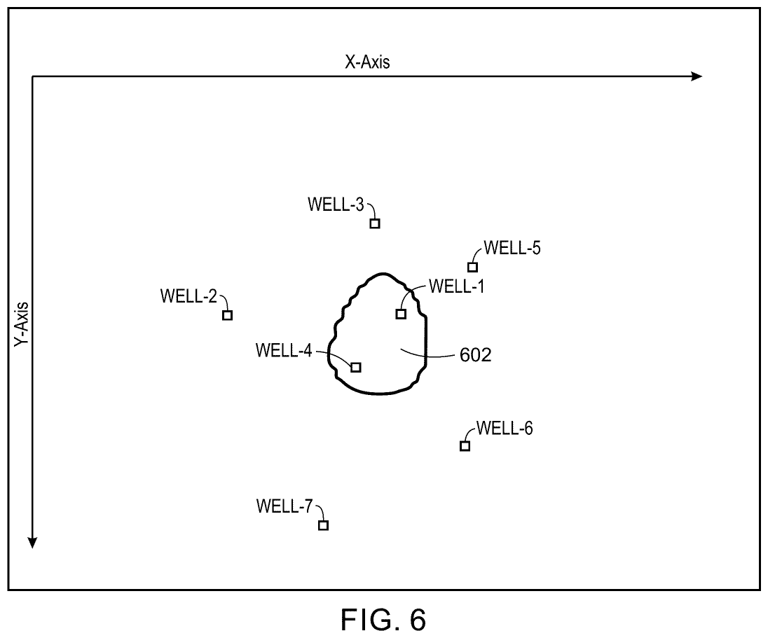

FIG. 6 illustrates an example 2D baffle map for layer 2 (according to baffle data for layer 2 in FIG. 5), according to some implementations. The circle 602 indicates locations of inter-layer baffles (locations of wells) in layer 2 of a reservoir.

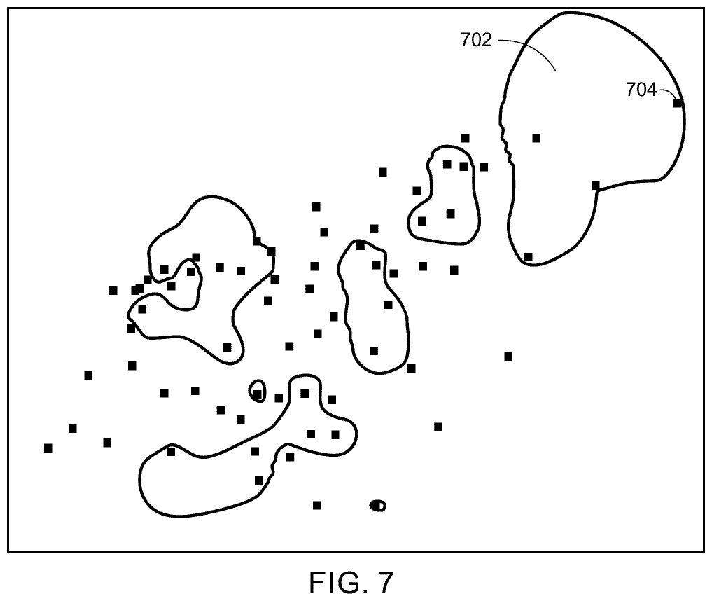

FIG. 7 illustrates another example 2D baffle map generated by the baffle identification process, according to some implementations. The circles (e.g., circle 702) represent areas where pressure baffles are predicted to be present based on FTS data. The dots (e.g., dot 704) represent wells with FTS data.

Five, the 2D maps (each map corresponds to its respective layer) can be exported as 3D baffle regions to integrate into a 3D simulation model and filtered according to the K index corresponding to respective geological layers (each 2D map corresponds to its respective layer). In the history matching phase of a simulation study, the baffle regions are used to modify vertical connectivity within the reservoir simulation model to better match observed data, e.g., a baffling effect observed in the FTS data. In the regions where pressure baffles are observed due to actual FTS data analysis, a vertical connectivity in the simulation model is also reduced. This can result in improved match of the simulation model to the differential depletion as observed in the actual FTS pressure data.

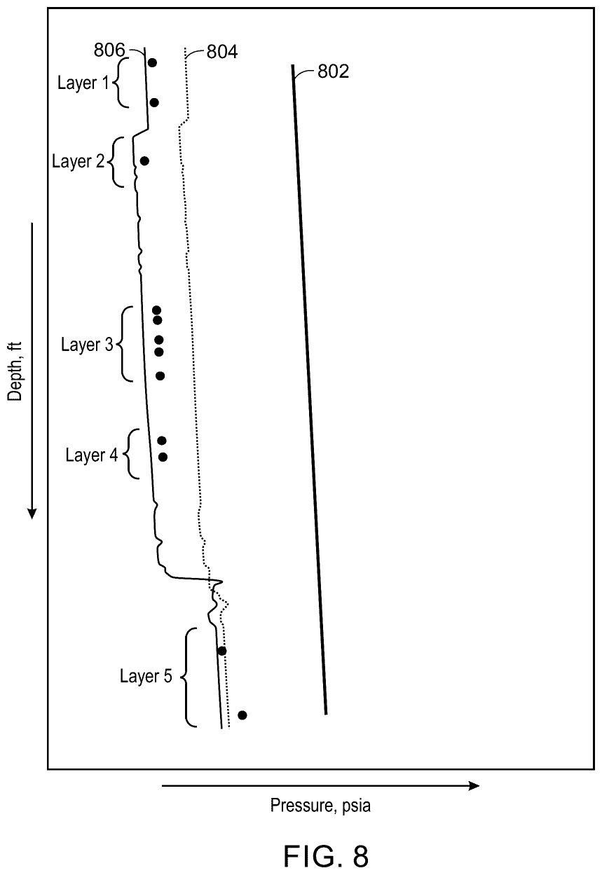

FIG. 8 illustrates improvement in simulation model history match quality of an example well, according to some implementations. The line 802 represents an initial pre-production simulation model pressure response (an initial oil gradient). The solid dots represent FTS data points acquired for a reservoir in the oil field. The line 804 represents the base simulation model pressure response before incorporating baffle regions. The line 806 represents the simulation model pressure response after incorporating baffle regions. As shown in FIG. 8, compared with the base simulation model pressure response 804, the simulation model pressure response 806 can match better with data points indicating actual FTS pressure data.

Furthermore, it is observed that the pressure baffles also play an important role in the movement of water in the reservoir. As seen in FIG. 7, As the baffles are interpreted to be laterally extensive, the water fluid in the simulation model moves preferentially on top of baffle regions. Thus, application of 3D baffle regions can lead to improved history match of the simulation model to the actual water-cut data at the wells because baffles are key part of the reservoir displacement mechanism in the reservoir and influence the flow paths, sweep efficiency, and pressure distribution within the reservoir.

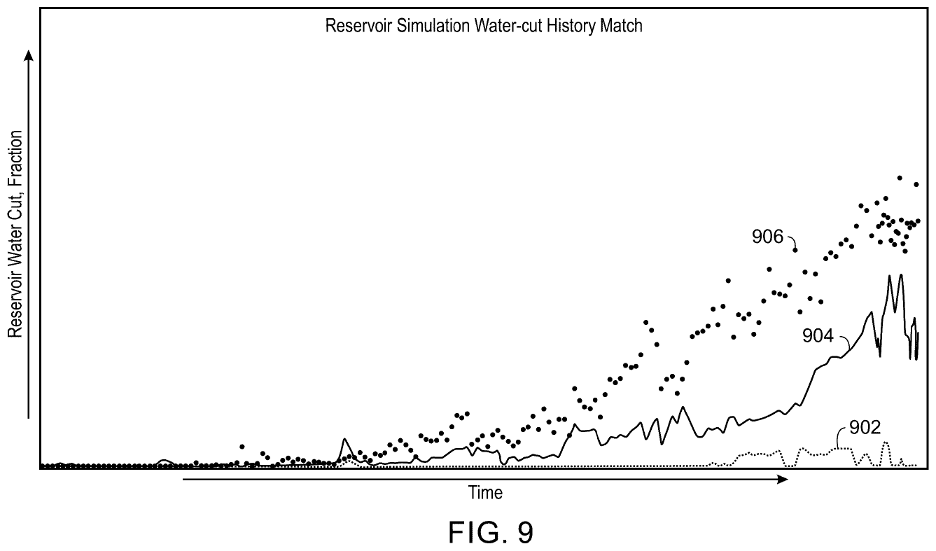

FIG. 9 illustrates an improvement in reservoir water-cut history match quality after incorporating baffle regions property that are used for history match calibration, according to some implementations. The dots 906 represent actual data, the line 902 represents the base simulation model water cut response, and the line 904 represents the simulation model response after application of 3D baffle regions. A water-cut history match in a reservoir simulation model refers to a process of adjusting the simulation model to replicate observed water-cut data over time, enabling the simulation model to accurately reflect the reservoir's real-world production behavior. The water cut is a ratio of water to the total liquid (oil and water) produced from a well, and history matching involves fine-tuning the simulation model to match actual field data, including the water cut.

Incorporating baffle regions into the simulation model can enhance its ability to accurately represent the reservoir fluid displacement mechanism. The resulting calibrated simulation model becomes a better tool for prediction studies such as field development and forecasting, because it accurately captures the subsurface reservoir behavior. Furthermore, the automation in the disclosed techniques enables a rapid progress significantly reducing the time needed to complete the simulation study.

### Example Automatic Baffle Identification Process

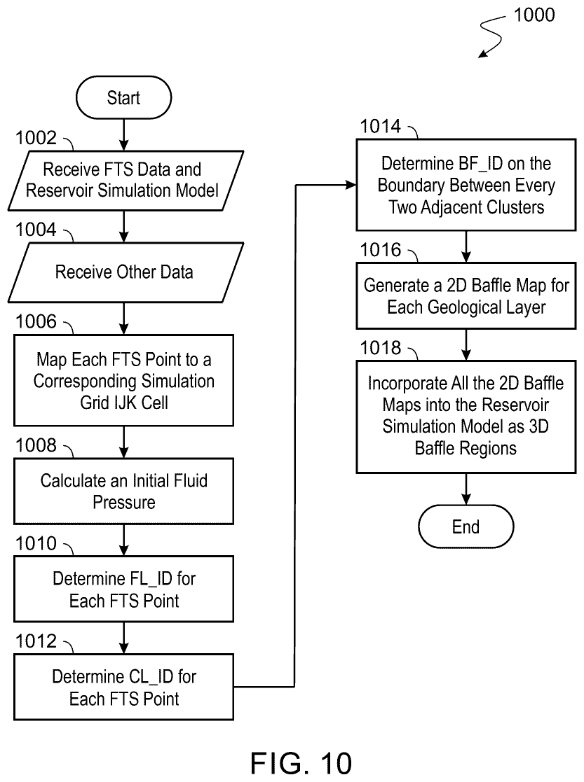

FIG. 10 illustrates a flow chart of an example process for automatic baffle identification, according to one or more implementations. Process 1000 is described as being performed by a computing device including one or more processors or a controller, such as controller 1300 of FIG. 13. The example process 1000 shown in FIG. 10 can be modified or reconfigured to include additional, fewer, or different steps (not shown in FIG. 10), which can be performed in the order shown or in a different order.

The following parameters are used for baffle identification: (i) FTS pressure versus depth data for multiple wells (psi vs. feet); (ii) Reservoir simulation model initialized with relevant static and dynamic reservoir parameters (grid, porosity, permeability, water saturation); (iii) Geological layering key with respect to simulation grid K index (layer-name, First K Index, Last K Index); (iv) Reservoir fluid densities (gas/oil/water) (grams per cubic centimeter (g/cc) units); (v) Initial reservoir pressure at datum depth (psi at feet); (vi) Free water level depth (feet); (vii) Water saturation well logs (measured depth in feet vs. water saturation as a fraction value); Water saturation cut-off value (a fraction value); (viii) Threshold pressure value for pressure baffle identification (psi).

At 1002, the controller receives FTS data and a reservoir simulation model.

At 1004, the controller receives data including one or more of a geological layering key, reservoir fluid densities, an initial reservoir pressure at datum depth, a free water level depth, water saturation well logs, water saturation cut-off value, threshold pressure value for pressure baffle identification.

At 1006, the controller maps each FTS point with a corresponding simulation grid IJK cell using subsurface spatial data (e.g., IJK index perforation data). Each FTS point corresponds to a different simulation grid cell.

At 1008, the controller calculates an initial fluid pressure (e.g., oil and water pressures), according to equations (2)-(4) described above.

At 1010, the controller determines FL_ID for each FTS point, according to equation (5). FL_ID indicates a category of a zone where each FTS point is located.

At 1012, the controller determines CL_ID for each FTS point based on the minimum and maximum predicted pressures of the next FTS point, according to equation (8). CL_ID indicates a cluster for each FTS point.

At 1014, the controller determines BF_ID on the boundary between every two adjacent clusters. BF_ID indicates whether a pressure baffle is present on the boundary.

At 1016, the controller generates a 2D baffle map for each geological layer. The 2D baffle map indicates the locations of pressure baffles.

At 1018, the controller incorporates all the 2D baffle maps into the reservoir simulation model as 3D baffle regions.

The disclosed techniques can automatically identify pressure baffles observed in multiple FTS data without human intervention. The disclosed techniques provide a standardized method of identifying reservoir fluid status for each FTS point using initial water saturation obtained from the simulation model and water saturation logs. The disclosed techniques enable reservoir level learnings to be generated for pressure baffles at the level of each geological layer. The disclosed techniques can improve a simulation model, so that the simulation model can match the actual FTS pressure response and actual water-cut response in the reservoir. The disclosed techniques can remove human subjectivity in the pressure baffle analysis of FTS pressure data. The automation of the process allows for rapid analysis of hundreds of wells which would have been tedious with human efforts.

Each FTS point is mapped to an IJK grid cell in the reference simulation grid. A geological layer is identified using the K index of each point in the grid. An initial water saturation value of each point can be obtained directly from the simulation model. Then initial oil and water pressures are calculated, and water saturation values can be obtained for every FTS point from water saturation logs. The reservoir saturation status can be identified using a FL_ID parameter, indicating whether a zone where each FTS point is present is an oil zone, swept zone, or high water-saturation zone (e.g., aquifer or tight reservoir).

A baffle identification process then calculates a Boolean parameter BF_ID that identifies pressure baffles both within geological layers (intra-layer) and at the transition boundary between two different geological layers (inter-layer). The inter-layer baffles are mapped between wells using 2D kriging interpolation method.

The resulting 2D maps provide information on baffles at the boundary of each geological layer. The 2D maps are directly exported to simulation models as 3D regions and utilized as history match calibration parameters. It has been observed that performing simulation model calibration using the baffle regions not only improves simulation model match on FTS pressure data, but also improves the match quality of water movement in the reservoir and the match on water production rates.

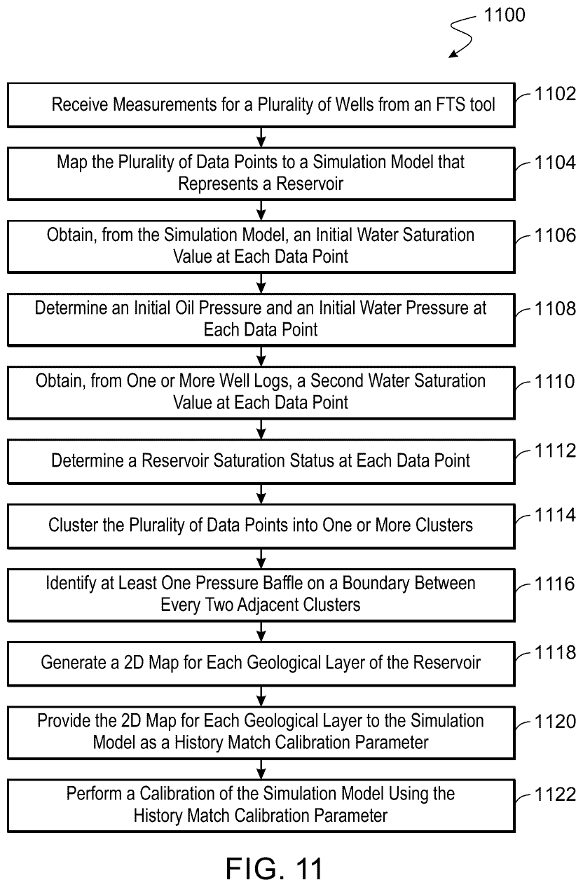

FIG. 11 illustrates a flow chart of an example process 1100 for automatic baffle identification, according to some implementations. Process 1100 is described as being performed by a computing device including one or more processors or a controller, such as controller 1300 of FIG. 13. The example process 1100 shown in FIG. 11 can be modified or reconfigured to include additional, fewer, or different steps (not shown in FIG. 11), which can be performed in the order shown or in a different order.

At 1102, the controller receives measurements for a plurality of wells from an FTS tool. The measurements include a plurality of data points (e.g., FTS data points), and each data point is associated with a different pressure value.

At 1104, the controller maps the plurality of data points to a simulation model that represents a reservoir. The simulation model is structured as an IJK grid including a plurality of grid cells. Each data point is mapped to a different IJK grid cell.

At 1106, the controller obtains, from the simulation model, an initial water saturation value at each data point. The initial water saturation value (e.g., SWINIT) at each point can be obtained directly from the simulation model.

At 1108, the controller determines an initial oil pressure and an initial water pressure at each data point using a free water level, an initial reservoir pressure at a datum depth, and a fluid density including a water density and an oil density. The initial oil pressure and the initial water pressure can be determined using equations (2)-(4).

At 1110, the controller obtains, from one or more well logs (e.g., water saturation logs), a second water saturation value (e.g., LOGSW) at each data point.

At 1112, the controller determines a reservoir saturation status (represented by FL_ID) at each data point using the initial water saturation value and the second water saturation value (e.g., LOGSW).

At 1114, the controller clusters the plurality of data points into one or more clusters (represented by CL_ID) based on an actual pressure value at each data point in the measurements performed by the FTS, the fluid density at each data point and the reservoir saturation status (represented by FL_ID) at each data point.

At 1116, the controller identifies at least one pressure baffle (represented by BF_ID) on a boundary between every two adjacent clusters.

At 1118, the controller generates a 2D map for each geological layer of the reservoir, indicating a location of each pressure baffle. The location of each pressure baffle on the 2D map is shown as a location of the corresponding well, e.g., as illustrated in FIGS. 6 and 7.

At 1120, the controller provides the 2D map for each geological layer to the simulation model as a history match calibration parameter. The 2D maps can be exported as 3D baffle regions to integrate into the 3D simulation model.

At 1122, the controller performs a calibration of the simulation model using the history match calibration parameter. The calibration can enable a better match between simulation model pressure/water-cut response and actual FTS pressure/water-cut data.

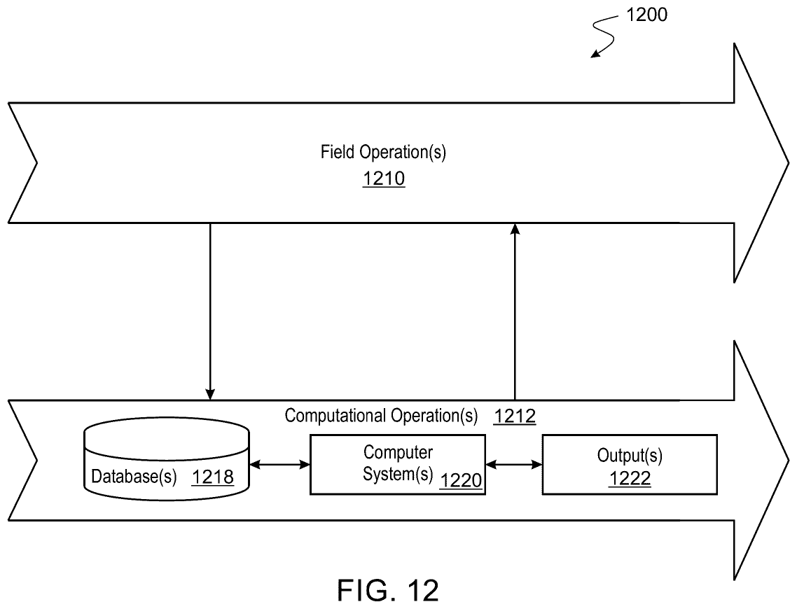

FIG. 12 illustrates hydrocarbon production operations 1200 that include both one or more field operations 1210 and one or more computational operations 1212, which exchange information and control exploration for the production of hydrocarbons, according to some implementations. In some implementations, outputs of techniques of the present disclosure can be performed before, during, or in combination with the hydrocarbon production operations 1200, specifically, for example, either as field operations 1210 or computational operations 1212, or both.

Examples of field operations 1210 include forming/drilling a wellbore, hydraulic fracturing, producing through the wellbore, and injecting fluids (such as water) through the wellbore, to name a few. In some implementations, methods of the present disclosure can trigger or control the field operations 1210. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 1210 and responsively triggering the field operations 1210 including, for example, generating plans and signals that provide feedback to and control physical components of the field operations 1210. Alternatively, or in addition, the field operations 1210 can trigger the methods of the present disclosure. For example, implementing physical components (including, for example, hardware, such as sensors) deployed in the field operations 1210 can generate plans and signals that can be provided as input or feedback (or both) to the methods of the present disclosure.

Examples of computational operations 1212 include one or more computer systems 1220 that include one or more processors and computer-readable media (e.g., non-transitory computer-readable media) operatively coupled to the one or more processors to execute computer operations to perform the methods of the present disclosure. The computational operations 1212 can be implemented using one or more databases 1218, which store data received from the field operations 1210 and/or generated internally within the computational operations 1212 (e.g., by implementing the methods of the present disclosure) or both. For example, the one or more computer systems 1220 process inputs from the field operations 1210 to assess conditions in the physical world, the outputs of which are stored in the databases 1218. For example, seismic sensors of the field operations 1210 can be used to perform a seismic survey to map subterranean features, such as facies and faults. In performing a seismic survey, seismic sources (e.g., seismic vibrators or explosions) generate seismic waves that propagate in the Earth, and seismic receivers (e.g., geophones) measure reflections generated as the seismic waves interact with boundaries between layers of a subsurface formation. The source and received signals are provided to the computational operations 1212 where they are stored in the databases 1218 and analyzed by the one or more computer systems 1220.

In some implementations, one or more outputs 1222 generated by the one or more computer systems 1220 can be provided as feedback/input to the field operations 1210 (either as direct input or stored in the databases 1218). The field operations 1210 can use the feedback/input to control physical components used to perform the field operations 1210 in the real world.

For example, the computational operations 1212 can process the seismic data to generate three-dimensional (3D) maps of the subsurface formation. The computational operations 1212 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 1212 to process new information about the formation and control the drilling to adjust to the observed conditions in real time.

The one or more computer systems 1220 can update the 3D maps of the subsurface formation as information from one exploration well is received, and the computational operations 1212 can adjust the location of the next exploration well based on the updated 3D maps. Similarly, the data received from production operations can be used by the computational operations 1212 to control components of the production operations. For example, production well and pipeline data can be analyzed to predict slugging in pipelines leading to a refinery, and the computational operations 1212 can control machine operated valves upstream of the refinery to reduce the likelihood of plant disruptions that run the risk of taking the plant offline.

In some implementations of the computational operations 1212, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

FIG. 13 is a schematic illustration of an example controller 1300 (or control system) that enables an example system to identify wells where baffles are present and generate a two-dimensional (2D) map indicating locations of baffles at each geological layer of a reservoir, according to some implementations. For example, the controller 1300 may be operable according to the processes 1000 and 1100 of FIGS. 10 and 11. The controller 1300 is intended to include various forms of digital computers, such as printed circuit boards (PCB), processors, digital circuitry, or otherwise parts of a system for supply chain alert management. Additionally, the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 1300 includes a processor 1310, a memory 1320, a storage device 1330, and an input/output interface 1340 communicatively coupled with input/output devices 1360 (for example, displays, keyboards, measurement devices, sensors, valves, pumps). Each of the components 1310, 1320, 1330, and 1340 are interconnected using a system bus 1350. The processor 1310 is capable of processing instructions for execution within the controller 1300. The processor may be designed using any of a number of architectures. For example, the processor 1310 may be a CISC (Complex Instruction Set Computers) processor, a RISC (Reduced Instruction Set Computer) processor, or a MISC (Minimal Instruction Set Computer) processor.

In one implementation, the processor 1310 is a single-threaded processor. In another implementation, the processor 1310 is a multi-threaded processor. The processor 1310 is capable of processing instructions stored in the memory 1320 or on the storage device 1330 to display graphical information for a user interface on the input/output interface 1340.

The memory 1320 stores information within the controller 1300. In one implementation, the memory 1320 is a computer-readable medium. In one implementation, the memory 1320 is a volatile memory unit. In another implementation, the memory 1320 is a non-volatile memory unit.

The storage device 1330 is capable of providing mass storage for the controller 1300. In one implementation, the storage device 1330 is a computer-readable medium. In various different implementations, the storage device 1330 may be a floppy disk device, a hard disk device, an optical disk device, or a tape device.

The input/output interface 1340 provides input/output operations for the controller 1300. In one implementation, the input/output devices 1360 include a keyboard and/or pointing device. In another implementation, the input/output devices 1360 includes a display unit for displaying graphical user interfaces.

There can be any number of controllers 1300 associated with, or external to, a computer system containing controller 1300, with each controller 1300 communicating over a network. Further, the terms “client,” “user,” and other appropriate terminology can be used interchangeably, as appropriate, without departing from the scope of the present disclosure. Moreover, the present disclosure contemplates that many users can use one controller 1300, and one user can use multiple controllers 1300.

### EMBODIMENTS/EXAMPLES

According to some non-limiting embodiments or examples, provided is a computer-implemented method for baffle identification implemented by one or more processors, comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

According to some non-limiting embodiments or examples, provided is an apparatus comprising a non-transitory, computer readable, storage medium that stores instructions that, when executed by at least one processor, cause the at least one processor to perform operations comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

According to some non-limiting embodiments or examples, provided is a system, comprising: one or more memory modules; and one or more hardware processors communicably coupled to the one or more memory modules, the one or more hardware processors configured to execute instructions stored on the one or more memory modules to perform operations comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

Further non-limiting aspects or embodiments are set forth in the following numbered embodiments:

Embodiment 1: A computer-implemented method for baffle identification implemented by one or more processors, the method comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

Embodiment 2: The computer-implemented method of Embodiment 1, wherein clustering the plurality of data points into the one or more clusters further comprises: for each data point: identifying a true TVD and an actual pressure value at a current data point; predicting a pressure value at the next adjacent data point based on the actual pressure value at the current data point, the fluid density, and a difference between a TVD of the next adjacent data point and the TVD of the current data point; comparing an actual pressure value at the next adjacent data point with the predicted pressure value; and assigning the next adjacent data point into a cluster based on the comparison.

Embodiment 3: The computer-implemented method of Embodiment 2, wherein assigning the next adjacent data point into the cluster comprises: in response to the actual pressure value at the next adjacent data point being within a first pressure range, assigning the next adjacent data point into a cluster the same as that of the current data point; in response to the actual pressure value at the next adjacent data point being within a second pressure range, assigning the next adjacent data point into a new cluster different from that of the current data point.

Embodiment 4: The computer-implemented method of Embodiment 2, wherein the fluid density comprises a maximum density value and a minimum density value, and the predicted pressure value comprises a maximum predicted pressure value and a minimum predicted pressure value corresponding to the maximum density value and the minimum density value, respectively.

Embodiment 5: The computer-implemented method of Embodiment 1, wherein each grid cell includes a row (I) index, a column (J) index and a layer (K) index.

Embodiment 6: The computer-implemented method of Embodiment 1, wherein the reservoir saturation status at each data point indicates whether each data point is located in an oil zone, a swept zone, an aquifer zone, or a low-quality reservoir zone.

Embodiment 7: The computer-implemented method of Embodiment 1, further comprising: determining a location of at least one pressure baffle; determining that the at least one pressure baffle is an intra-geological layer pressure baffle or an inter-geological layer pressure baffle based on the location of the at least one pressure baffle.

Embodiment 8: The computer-implemented method of Embodiment 1, wherein identifying the at least one pressure baffle on the boundary between every two adjacent clusters further comprises identifying the at least one pressure baffle between a last data point in a first cluster and a first data point in a second cluster adjacent to the first cluster.

Embodiment 9: The computer-implemented method of Embodiment 1, wherein generating the 2D map for each geological layer of the reservoir comprises mapping pressure baffles identified in the plurality of wells aerially in an XY direction using a 2D surface mapping algorithm.

Embodiment 10: The computer-implemented method of Embodiment 9, wherein the 2D surface mapping algorithm comprises a kriging interpolation.

Embodiment 11: The computer-implemented method of Embodiment 1, wherein performing the calibration of the simulation model comprises adjusting a simulation model pressure response and a simulation model water-cut response using the history match calibration parameter.

Embodiment 12: A non-transitory, computer-readable medium storing one or more instructions executable by a computer system to perform one or more operations, comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

Embodiment 13: The non-transitory, computer-readable medium of Embodiment 12, wherein clustering the plurality of data points into the one or more clusters further comprises: for each data point: identifying a true TVD and an actual pressure value at a current data point; predicting a pressure value at the next adjacent data point based on the actual pressure value at the current data point, the fluid density, and a difference between a TVD of the next adjacent data point and the TVD of the current data point; comparing an actual pressure value at the next adjacent data point with the predicted pressure value; and assigning the next adjacent data point into a cluster based on the comparison.

Embodiment 14: The non-transitory, computer-readable medium of Embodiment 13, wherein assigning the next adjacent data point into the cluster comprises: in response to the actual pressure value at the next adjacent data point being within a first pressure range, assigning the next adjacent data point into a cluster the same as that of the current data point; in response to the actual pressure value at the next adjacent data point being within a second pressure range, assigning the next adjacent data point into a new cluster different from that of the current data point.

Embodiment 15: The non-transitory, computer-readable medium of Embodiment 13, wherein the fluid density comprises a maximum density value and a minimum density value, and the predicted pressure value comprises a maximum predicted pressure value and a minimum predicted pressure value corresponding to the maximum density value and the minimum density value, respectively.

Embodiment 16: The non-transitory, computer-readable medium of Embodiment 12, wherein each grid cell includes a row (I) index, a column (J) index and a layer (K) index.

Embodiment 17: The non-transitory, computer-readable medium of Embodiment 12, wherein the reservoir saturation status at each data point indicates whether each data point is located in an oil zone, a swept zone, an aquifer zone, or a low-quality reservoir zone.

Embodiment 18: The non-transitory, computer-readable medium of Embodiment 12, further comprising: determining a location of at least one pressure baffle; determining that the at least one pressure baffle is an intra-geological layer pressure baffle or an inter-geological layer pressure baffle based on the location of the at least one pressure baffle.

Embodiment 19: The non-transitory, computer-readable medium of Embodiment 12, wherein identifying the at least one pressure baffle on the boundary between every two adjacent clusters further comprises identifying the at least one pressure baffle between a last data point in a first cluster and a first data point in a second cluster adjacent to the first cluster.

Embodiment 20: A computer-implemented system, comprising: one or more computers; and one or more computer memory devices interoperably coupled with the one or more computers and having tangible, non-transitory, machine-readable media storing one or more instructions that, when executed by the one or more computers, perform one or more operations, comprising: receiving, measurements for a plurality of wells from an FTS tool, wherein the measurements comprise a plurality of data points and each data point is associated with a different pressure value; mapping the plurality of data points to a simulation model that represents a reservoir; obtaining, from the simulation model, an initial water saturation value at each data point; determining an initial oil pressure and an initial water pressure at each data point using a free water level, an initial reservoir pressure at a datum depth, and a fluid density comprising a water density and an oil density; obtaining, from one or more well logs, a second water saturation value at each data point; determining a reservoir saturation status at each data point using the initial water saturation value and the second water saturation value; clustering the plurality of data points into one or more clusters based on an actual pressure value at each data point in the measurements performed by the FTS tool, the fluid density at each data point and the reservoir saturation status at each data point; identifying at least one pressure baffle on a boundary between every two adjacent clusters; generating a 2D map for each geological layer of the reservoir indicating a location of each pressure baffle; providing the 2D map for each geological layer to the simulation model as a history match calibration parameter; and performing a calibration of the simulation model using the history match calibration parameter.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship. Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Various components may be described as performing a task or tasks, for convenience in the description. Such descriptions should be interpreted as including the phrase “configured to.” Reciting a component that is configured to perform one or more tasks is expressly intended not to invoke 35 USC § 112 (f) interpretation for that component.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

We claim:

1. A computer-implemented method for baffle identification implemented by one or more processors, the method comprising:
receiving, measurements for a plurality of wells from a Formation Testing and Sampling (FTS) tool, wherein the measurements comprise a plurality of data points and each data point is associated with a different pressure value;
mapping the plurality of data points to a simulation model that represents a reservoir;
obtaining, from the simulation model, an initial water saturation value at each data point;
determining an initial oil pressure and an initial water pressure at each data point using a free water level, an initial reservoir pressure at a datum depth, and a fluid density comprising a water density and an oil density;
obtaining, from one or more well logs, a second water saturation value at each data point;
determining a reservoir saturation status at each data point using the initial water saturation value and the second water saturation value;
clustering the plurality of data points into one or more clusters based on an actual pressure value at each data point in the measurements performed by the FTS tool, the fluid density at each data point and the reservoir saturation status at each data point;
identifying at least one pressure baffle on a boundary between every two adjacent clusters;
generating a two-dimensional (2D) map for each geological layer of the reservoir indicating a location of each pressure baffle;
providing the 2D map for each geological layer to the simulation model as a history match calibration parameter; and
performing a calibration of the simulation model using the history match calibration parameter.

2. The computer-implemented method of claim 1, wherein clustering the plurality of data points into the one or more clusters further comprises:
for each data point:
identifying a true vertical depth (TVD) and an actual pressure value at a current data point;
predicting a pressure value at the next adjacent data point based on the actual pressure value at the current data point, the fluid density, and a difference between a TVD of the next adjacent data point and the TVD of the current data point;
comparing an actual pressure value at the next adjacent data point with the predicted pressure value; and
assigning the next adjacent data point into a cluster based on the comparison.

3. The computer-implemented method of claim 2, wherein assigning the next adjacent data point into the cluster comprises:
in response to the actual pressure value at the next adjacent data point being within a first pressure range,
assigning the next adjacent data point into a cluster the same as that of the current data point;
in response to the actual pressure value at the next adjacent data point being within a second pressure range,
assigning the next adjacent data point into a new cluster different from that of the current data point.

4. The computer-implemented method of claim 2, wherein the fluid density comprises a maximum density value and a minimum density value, and the predicted pressure value comprises a maximum predicted pressure value and a minimum predicted pressure value corresponding to the maximum density value and the minimum density value, respectively.

5. The computer-implemented method of claim 1, wherein each grid cell includes a row (I) index, a column (J) index and a layer (K) index.

6. The computer-implemented method of claim 1, wherein the reservoir saturation status at each data point indicates whether each data point is located in an oil zone, a swept zone, an aquifer zone, or a low-quality reservoir zone.

7. The computer-implemented method of claim 1, further comprising:
determining a location of at least one pressure baffle;
determining that the at least one pressure baffle is an intra-geological layer pressure baffle or an inter-geological layer pressure baffle based on the location of the at least one pressure baffle.

8. The computer-implemented method of claim 1, wherein identifying the at least one pressure baffle on the boundary between every two adjacent clusters further comprises identifying the at least one pressure baffle between a last data point in a first cluster and a first data point in a second cluster adjacent to the first cluster.

9. The computer-implemented method of claim 1, wherein generating the 2D map for each geological layer of the reservoir comprises mapping pressure baffles identified in the plurality of wells aerially in a XY direction using a 2D surface mapping algorithm.

10. The computer-implemented method of claim 9, wherein the 2D surface mapping algorithm comprises a kriging interpolation.

11. The computer-implemented method of claim 1, wherein performing the calibration of the simulation model comprises adjusting a simulation model pressure response and a simulation model water-cut response using the history match calibration parameter.

12. A non-transitory, computer-readable medium storing one or more instructions executable by a computer system to perform one or more operations, comprising:
receiving, measurements for a plurality of wells from a Formation Testing and Sampling (FTS) tool, wherein the measurements comprise a plurality of data points and each data point is associated with a different pressure value;
mapping the plurality of data points to a simulation model that represents a reservoir;
obtaining, from the simulation model, an initial water saturation value at each data point;
determining an initial oil pressure and an initial water pressure at each data point using a free water level, an initial reservoir pressure at a datum depth, and a fluid density comprising a water density and an oil density;
obtaining, from one or more well logs, a second water saturation value at each data point;
determining a reservoir saturation status at each data point using the initial water saturation value and the second water saturation value;
clustering the plurality of data points into one or more clusters based on an actual pressure value at each data point in the measurements performed by the FTS tool, the fluid density at each data point and the reservoir saturation status at each data point;
identifying at least one pressure baffle on a boundary between every two adjacent clusters;
generating a two-dimensional (2D) map for each geological layer of the reservoir indicating a location of each pressure baffle;
providing the 2D map for each geological layer to the simulation model as a history match calibration parameter; and
performing a calibration of the simulation model using the history match calibration parameter.

13. The non-transitory, computer-readable medium of claim 12, wherein clustering the plurality of data points into the one or more clusters further comprises:
for each data point:
identifying a true vertical depth (TVD) and an actual pressure value at a current data point;
predicting a pressure value at the next adjacent data point based on the actual pressure value at the current data point, the fluid density, and a difference between a TVD of the next adjacent data point and the TVD of the current data point;
comparing an actual pressure value at the next adjacent data point with the predicted pressure value; and
assigning the next adjacent data point into a cluster based on the comparison.

14. The non-transitory, computer-readable medium of claim 13, wherein assigning the next adjacent data point into the cluster comprises:
in response to the actual pressure value at the next adjacent data point being within a first pressure range,
assigning the next adjacent data point into a cluster the same as that of the current data point;
in response to the actual pressure value at the next adjacent data point being within a second pressure range,
assigning the next adjacent data point into a new cluster different from that of the current data point.

15. The non-transitory, computer-readable medium of claim 13, wherein the fluid density comprises a maximum density value and a minimum density value, and the predicted pressure value comprises a maximum predicted pressure value and a minimum predicted pressure value corresponding to the maximum density value and the minimum density value, respectively.

16. The non-transitory, computer-readable medium of claim 12, wherein each grid cell includes a row (I) index, a column (J) index and a layer (K) index.

17. The non-transitory, computer-readable medium of claim 12, wherein the reservoir saturation status at each data point indicates whether each data point is located in an oil zone, a swept zone, an aquifer zone, or a low-quality reservoir zone.

18. The non-transitory, computer-readable medium of claim 12, further comprising:
determining a location of at least one pressure baffle;
determining that the at least one pressure baffle is an intra-geological layer pressure baffle or an inter-geological layer pressure baffle based on the location of the at least one pressure baffle.

19. The non-transitory, computer-readable medium of claim 12, wherein identifying the at least one pressure baffle on the boundary between every two adjacent clusters further comprises identifying the at least one pressure baffle between a last data point in a first cluster and a first data point in a second cluster adjacent to the first cluster.

20. A computer-implemented system, comprising:
one or more computers; and
one or more computer memory devices interoperably coupled with the one or more computers and having tangible, non-transitory, machine-readable media storing one or more instructions that, when executed by the one or more computers, perform one or more operations, comprising:
receiving, measurements for a plurality of wells from a Formation Testing and Sampling (FTS) tool, wherein the measurements comprise a plurality of data points and each data point is associated with a different pressure value;
mapping the plurality of data points to a simulation model that represents a reservoir;
obtaining, from the simulation model, an initial water saturation value at each data point;
determining an initial oil pressure and an initial water pressure at each data point using a free water level, an initial reservoir pressure at a datum depth, and a fluid density comprising a water density and an oil density;
obtaining, from one or more well logs, a second water saturation value at each data point;
determining a reservoir saturation status at each data point using the initial water saturation value and the second water saturation value;
clustering the plurality of data points into one or more clusters based on an actual pressure value at each data point in the measurements performed by the FTS tool, the fluid density at each data point and the reservoir saturation status at each data point;
identifying at least one pressure baffle on a boundary between every two adjacent clusters;
generating a two-dimensional (2D) map for each geological layer of the reservoir indicating a location of each pressure baffle;
providing the 2D map for each geological layer to the simulation model as a history match calibration parameter; and
performing a calibration of the simulation model using the history match calibration parameter.
